(19) United States
(12) Patent Application Publication
(10) Pub. No.: US 2010/0062158 A1
(43) Pub. Date: Mar. 11, 2010

(54) GAS SUPPLY METHOD AND GAS SUPPLY DEVICE

(75) Inventors: Masamichi Hara, Nirasaki-shi (JP); Atsushi Gomi, Nirasaki-shi (JP); Osamu Yokoyama, Nirasaki-shi (JP); Toshimasa Tanaka, Nirasaki-shi (JP); Shinji Maekawa, Nirasaki-shi (JP); Satoshi Taga, Nirasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/568,421

(22) Filed: Sep. 28, 2009

Related U.S. Application Data
(63) Continuation of application No. PCT/JP08/55747, filed on Mar. 26, 2008.

(30) Foreign Application Priority Data
Mar. 28, 2007 (JP) 2007-085652

(51) Int. Cl. C23C 16/448; C23C 16/52

(52) U.S. Cl. 427/255.28; 118/692

(57) ABSTRACT

A gas supply method supplies a source gas produced by heating and sublimating a solid source material in a source material container to a consuming area. The method includes the steps of: (a) flowing a carrier gas through a processing gas supply line and measuring a gas pressure therein; (b) heating the solid source material to produce the source gas; (c) supplying a carrier gas which has the same flow rate as the carrier gas in the step (a) to the source material container and measuring a gas pressure in the processing gas supply line while flowing the source gas together with the carrier gas through the processing gas supply line; and (d) calculating the flow rate of the source gas based on the pressure measurement values obtained in the steps (a) and (c), and the flow rate of the carrier gas.

This application is a Continuation Application of PCT International Application No. PCT/JP2008/055747 filed on Mar. 26, 2008, which designated the United States.

### FIELD OF THE INVENTION

The present invention relates to a technique for supplying a source gas produced by heating and sublimating a solid source material into a gas consuming area such as a processing chamber.

### BACKGROUND OF THE INVENTION

A CVD apparatus, for example, is used for an apparatus for forming a film, e.g., a metal film or the like, on a substrate. In this CVD apparatus, a flow rate of a processing gas to be supplied to a processing chamber where a substrate is mounted is controlled. The flow rate of the processing gas is measured by a flow rate measurement device such as a mass flow controller (MFC), a mass flow meter (MFM) or the like.

For example, when an MFC is used, there is provided a bypass line branched from a main gas channel and the flow rate of the processing gas is measured by measuring a temperature difference of the processing gas between e.g., two points in the corresponding bypass line after heating a processing gas therein.

Meanwhile, there is examined a method for forming a film by using a solid source material in order to increase crystal density after the film formation and reduce the amount of impurities introduced into a substrate (film). For example, a film forming apparatus 100 shown in FIG. 5 can be used for an apparatus for forming a film by using the method described above. The film forming apparatus 100 shown in FIG. 5 includes a carrier gas supply source 101, a source material container 102 and a processing chamber 103. When a carrier gas, e.g., N₂ gas, is supplied from the carrier gas supply source 101 into the source material container 102, a source gas produced by heating and sublimating a solid source material, e.g., ruthenium carbonyl (Ru₃(CO)₁₂), by a heater 112 in the source material container 102 is supplied together with the carrier gas into the processing chamber 103. In the processing chamber 103, the source gas is decomposed to form, e.g., ruthenium film, on a substrate 104.

In this film forming apparatus 100, a flow rate of the carrier gas is measured by an MFC 115 before the carrier gas is supplied into the source material container 102. Further, a total flow rate of the carrier gas and the source gas is measured by an MFC 116 installed in a processing gas supply line 106 before the carrier gas and the source gas are supplied into the processing chamber 103. A flow rate of the source gas is calculated by subtracting the flow rate of the carrier gas measured by the MFC 115 from the total the flow rate of the carrier gas and the source gas.

The above solid source material is disadvantageous in its difficulty of increasing its flow rate because of difficulty of sublimation due to a low vapor pressure. Therefore, in order to facilitate the sublimation of the solid source material, the supply amount of the source gas needs to be increased by minimizing the pressure in the source material container 102 and increasing the diameter of the processing gas supply line 106 up to, e.g., about 5 cm (2 inch). However, a line where a conventional flow rate measuring device (e.g., a commercial MFC) can be installed has a diameter of, e.g., about 0.95 cm (0.375 inch), which is considerably small. Such diameter of the line allows a very small supply amount of the source gas, so that throughput decreases considerably depending on processes. This makes it difficult to be applied to an actual film forming apparatus. Moreover, such diameter of the line may cause to increase a pressure at the upstream side of the line so that the sublimation of the solid source material cannot be facilitated.

### SUMMARY OF THE INVENTION

The present invention has been developed to effectively solve the above-described problems. An object of the present invention is to provide a technique capable of readily controlling a flow rate of a source gas, especially a technique capable of achieving a desired large flow rate of a source gas, in the case of supplying a source gas produced by heating and sublimating a solid source material to a gas consuming area such as a processing module.

In accordance with the present invention, there is provided a gas supply method for supplying a source gas produced by heating and sublimating a solid source material in a source material container to a consuming area, the gas supply method including the steps of: (a) flowing a carrier gas through a processing gas supply line that communicates with the consuming area and measuring a gas pressure in the processing gas supply line; (b) heating the solid source material contained in the source material container to produce the source gas; (c) supplying a carrier gas which has the same flow rate as the carrier gas in the step (a) to the source material container and measuring a gas pressure in the processing gas supply line while flowing the source gas together with the carrier gas through the processing gas supply line; and (d) calculating the flow rate of the source gas based on the pressure measurement value obtained in the step (a), the pressure measurement value obtained in the step (c), and the flow rate of the carrier gas.

In accordance with the present invention, there are any particular problems even if the pressure in the source material container is decreased, so that sublimation of the solid source material can be facilitated, and the flow rate of the source gas can be calculated very simply. As a result, the flow rate of the source gas can be readily controlled. Besides, in accordance with the present invention, a diameter of a line is not limited unlike in a conventional line using a flow rate measuring device such as a mass flow controller or the like, so that a large flow rate of the source gas can be ensured. These effects are very useful in realizing, e.g., a film forming apparatus using a solid source material.

The gas supply method described above may further include, after the step (d), a step of adjusting a flow rate of the source gas and controlling a heating temperature of the solid source material based on a preset flow rate of the source gas and the calculated flow rate of the source gas obtained in the step (d).

Preferably, an inner diameter of the processing gas supply line extended from the source material container to the consuming area may be greater than or equal to about 1.9 cm (0.75 inch).

Further, the consuming area may be a processing module for performing a film forming process on a substrate in a processing chamber by decomposing the source gas under the vacuum atmosphere.

In accordance with the present invention, there is provided a gas supply device for supplying a source gas produced by heating and sublimating a solid source material in a source material container to a consuming area, the gas supply device including: a source material container for storing therein a solid source material; a heating unit for heating the solid source material in the source material container; a carrier gas inlet line provided between a carrier gas supply source and the source material container; a processing gas supply line provided between the source material container and the consuming area; a bypass line installed between the carrier gas inlet line and the processing gas supply line; a pressure measuring unit provided at a downstream side of a connecting position of the bypass line on the processing gas supply line; a flow path switching unit for switching a flow path of the carrier gas between a flow path for causing the carrier gas to flow from the carrier gas inlet line to the processing gas supply line via the bypass line and a flow path for causing the carrier gas to flow from the carrier gas inlet line to the processing gas supply line via the source material container; and a controller for controlling a flow rate of the source gas flowing in the processing gas supply line.

Herein, the controller performs: storing a reference data including a measured flow rate of the carrier gas and a pressure measurement value obtained by the pressure measuring unit while the carrier gas is flowing in the processing gas supply line via the bypass line; obtaining a pressure measurement value by the pressure measuring unit while the carrier gas having the unaltered flow rate and the source gas are flowing together in the processing gas supply line via the source material container; and calculating a flow rate of the source gas based on the measured pressure measurement values and the reference data.

In accordance with the present invention, there are any particular problems even if the pressure in the source material container is decreased, so that sublimation of the solid source material can be facilitated, and the flow rate of the source gas can be calculated very simply. As a consequence, the flow rate of the source gas can be readily controlled. Further, in accordance with the present invention, a diameter of a line is not limited unlike in a conventional line using a flow rate measuring device such as a mass flow controller or the like, so that a large flow rate of the source gas can be ensured. These effects are very useful in realizing, e.g., a film forming apparatus using a solid source material.

Preferably, the controller may adjust a flow rate of the source gas and control a power supplied to the heating unit based on a preset flow rate of the source gas and a calculated flow rate of the source gas.

Further, an inner diameter of the processing gas supply line may be greater than or equal to about 1.9 cm (0.75 inch).

In accordance with the present invention, there is provided a semiconductor manufacturing apparatus including: the gas supply device included in any one of feature described above; a processing module including a processing chamber as a consuming area, for performing film formation on a substrate by decomposing a source gas under the vacuum atmosphere, wherein the controller has the reference data for film forming recipes executed in the processing module.

Further, In accordance with the present invention, there is provided a storage medium which stores therein a program used in a gas supply device for supplying a source gas produced by heating and sublimating a solid source material in a source material container to a consuming area, wherein the program includes steps of executing the gas supply method included in any one of features described above.

### BRIEF DESCRIPTION OF THE DRAWINGS

FIG. 1 is a schematic vertical cross sectional view showing an example of a semiconductor manufacturing apparatus including a gas supply unit in accordance with the present invention.

FIGS. 2A and 2B provide a characteristic graph illustrating a pressure measurement range of a pressure gauge used in the semiconductor manufacturing apparatus shown in FIG. 1.

FIG. 3 presents a schematic vertical cross sectional view depicting an example of a processing chamber for performing film formation in the semiconductor manufacturing apparatus shown in FIG. 1.

FIGS. 4A and 4B represent a conceptual diagram for explaining calculation of a flow rate of a source gas in the semiconductor manufacturing apparatus shown in FIG. 1.

FIG. 5 offers a schematic vertical cross sectional view showing an example of a conventional film forming apparatus.

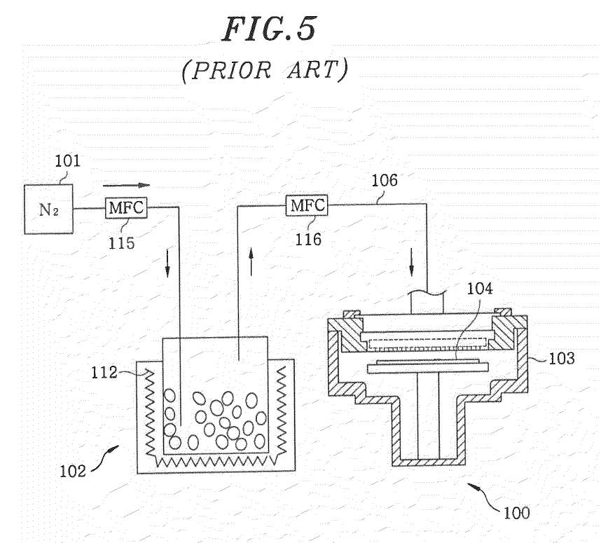

### DETAILED DESCRIPTION OF EMBODIMENT

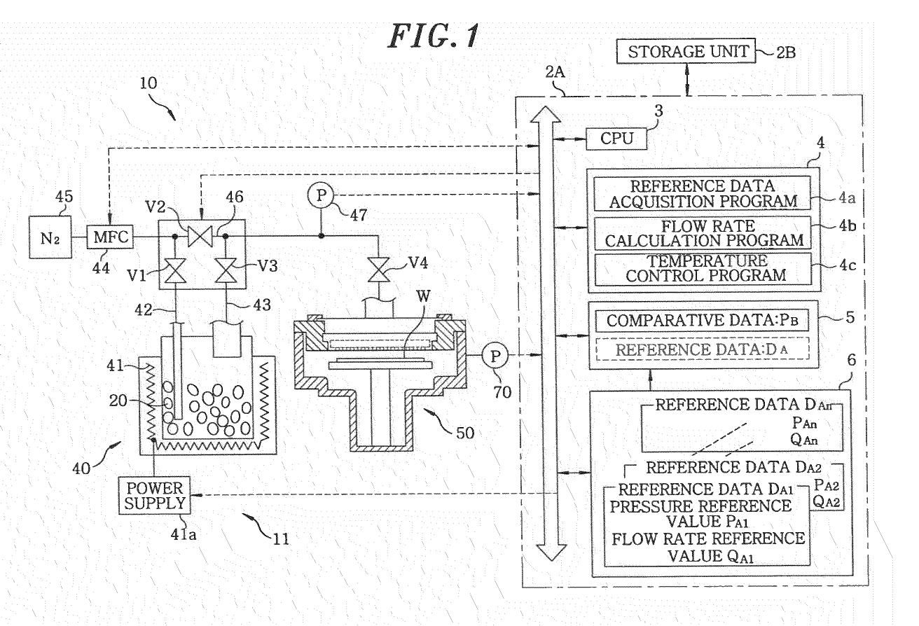

An example of a semiconductor device manufacturing apparatus including a gas supply unit in accordance with the present invention will be described with reference to FIG. 1. A semiconductor device manufacturing apparatus 10 shown in FIG. 1 includes a source material container 40 which stores therein a particle-shaped solid source material, e.g., ruthenium carbonyl Ru₃(CO)₁₂ (hereinafter, referred to as “solid source material 20”), and a processing module 50 for forming, e.g., a ruthenium film on a substrate, e.g., a semiconductor wafer (hereinafter, referred to as “wafer W”), by thermally decomposing a source gas produced by sublimating the solid source material 20.

The source material container 40 has therein a heating unit 41, e.g., a heater or the like, for producing a source gas sublimated by heating the solid source material 20. The heating unit 41 is connected with a power supply 41a. Further, a carrier gas inlet line 42 for introducing a carrier gas into the source material container 40 and a processing gas supply line 43 for supplying a source gas into the processing chamber 60 both have open ends inside the source material container 40. The upstream side of the carrier gas inlet line 42 is connected with a carrier gas supply source 45 which stores therein a carrier gas, e.g., N₂ gas or the like, via a valve V1 and a mass flow controller (MFC) 44.

The downstream side of the processing gas supply line 43 (the processing chamber 60 side) is connected to the processing chamber 60 serving as a consuming area via valves V3 and V4. Since the solid source material 20 has a low vapor pressure, the processing gas supply line 43 is formed to have a diameter, e.g., 5 cm (2 inch), larger than or equal to 1.9 cm (0.75 inch) to facilitate the sublimation of the source gas by decreasing the pressure in the source material container 40.

A bypass line 46 is installed between the carrier gas inlet line 42 and the processing gas supply line 43 so that the upstream side of the valve V1 (the carrier gas supply source 45 side) is connected with the downstream side of the valve V3 (the processing chamber 60 side). The bypass line 46 is provided with a valve V2. The valves V1, V2 and V3 form a flow path switching unit. Further, although a tape heater for heating a gas passing through the processing gas supply line 43 is attached to the processing gas supply line to thereby suppress sublimation (deposition) of the source gas, the illustration thereof is omitted.

Moreover, a pressure gauge 47 serving as a pressure measuring unit is provided between the valves V3 and V4. The pressure gauge 47 is provided to measure a gas pressure in the processing gas supply line 43 with high accuracy by shifting to a higher pressure side from a pressure measurement range of a conventional pressure gauge that measures a pressure in a high vacuum range.

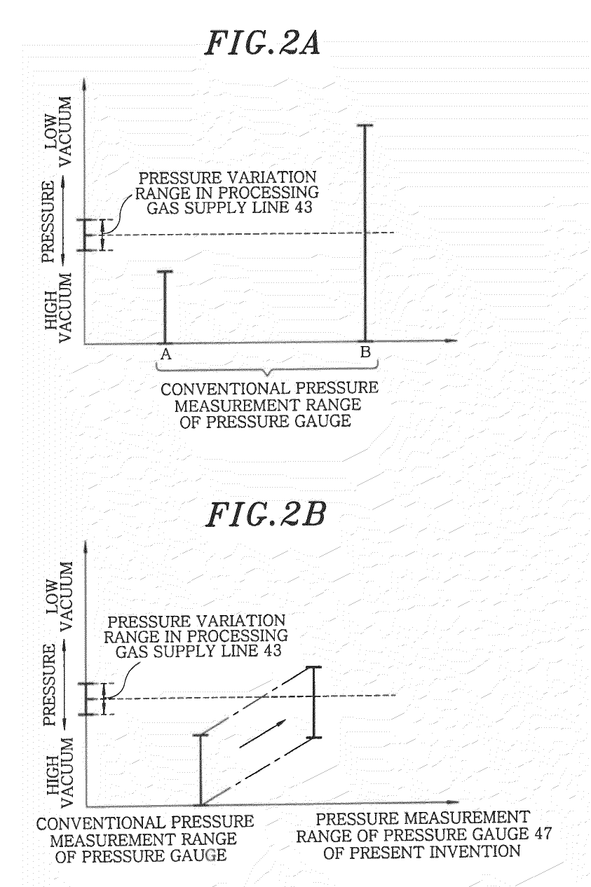

For example, in a pressure gauge (vacuum gauge) such as a capacitance manometer configured to measure a pressure by detecting a change of an electrostatic capacitance between metal thin films due to deformation thereof, the lower limit of the pressure measurement range is zero. However, a pressure gauge for measuring a pressure in a high vacuum range which is indicated by notation A in FIG. 2A does not have a wide pressure measurement range.

On the other hand, a pressure gauge for measuring a pressure in a low vacuum range which is indicated by notation B in FIG. 2A (hereinafter, may be referred to as “B pressure gauge”) offers a wide pressure measurement range compared to the pressure gauge indicated by notation A in FIG. 2A (hereinafter, may be referred to as “A pressure gauge”).

A maximum voltage output from these pressure gauges is normalized to, e.g., about 10 V. Therefore, when measuring a pressure in a low vacuum range, a pressure gauge which offers a wide pressure measurement range is required and, thus, resolution is reduced when it is used. On the other hand, a pressure gauge capable of measuring a pressure in a high vacuum range can provide high resolution, but the upper limit of the measurement range thereof is low (for example, that of the A pressure gauge is about 13.3 Pa (100 mTorr)). Further, the gas pressure in the processing gas supply line 43 is generally, e.g., about 17.3 Pa (130 mTorr), so that the A pressure gauge cannot be used and the B pressure gauge needs to be used.

Here, when the source gas produced by sublimating the solid source material is supplied to the processing chamber 60 together with the carrier gas, a partial pressure of the source gas in a mixture of the source gas and the carrier gas is low (e.g., a few mTorr) due to the low vapor pressure of the solid source material. However, the B pressure gauge does not provide high resolution capable of accurately detecting such a small pressure variation.

Therefore, it can be effective if the measurement range of the A pressure gauge is shifted to a higher pressure side. For example, by shifting the measurement pressure range of the pressure gauge 47 to a range from 100 mTorr to 200 mTorr, the range of the pressure in the processing gas supply line 43 can be detected with high accuracy. At that time, the pressure gauge 47 (A pressure gauge) is offset-controlled so that 0 V instead of 10 V is outputted at 100 mTorr which is the upper limit of the original pressure measurement range.

When the pressure measurement range of the pressure gauge 47 is shifted (offset-controlled) to a higher pressure side, the gain is adjusted so that the linearity between the pressure (vacuum level) and the output voltage can be maintained. Moreover, in the present embodiment, the carrier gas supply source 45, the MFC 44, the valves V1 to V3, the source material container 40, the carrier gas inlet line 42, the bypass line 46, the processing gas supply line 43 and the pressure gauge 47 are corresponding to the gas supply unit 11 in accordance with the present invention.

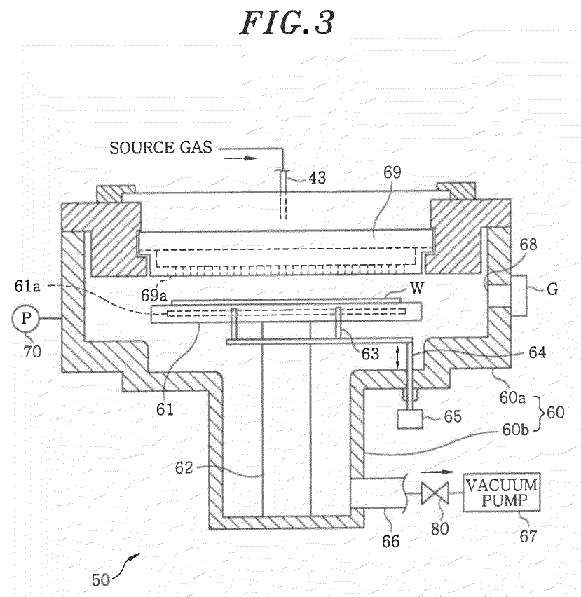

Hereinafter, the processing module 50 will be described with reference to FIG. 3. The processing chamber is formed in a so-called mushroom shape (T-shaped vertical cross section) in which an upper large-diameter cylindrical portion 60a and a lower small-diameter cylindrical portion 60b are connected to each other. A stage 61 serving as a mounting unit for mounting thereon a wafer W horizontally is provided inside the processing chamber 60. The stage 61 is supported on a bottom portion of the small-diameter cylindrical portion 60b via a supporting member 62.

The stage 61 has therein a heater 61a serving as a gas decomposition unit and an electrostatic chuck (not shown) for attracting and holding the wafer W. Moreover, the stage 61 is provided with, e.g., three elevating pins 63 (only two are shown for convenience) that can be projected from and retracted into a surface of the stage 61, such that the elevating pins 63 move the wafer W up and down to perform a transfer of the wafer W from and to a transfer unit (not shown). These elevating pins 63 are connected with an elevation mechanism 65 provided outside the processing chamber 60 via the supporting member 64. One end of a gas exhaust line 66 is connected to a bottom portion of the processing chamber 60. The other end of the gas exhaust line 66 is connected to a vacuum pump 67 serving as a vacuum exhaust unit via a butterfly valve 80. Furthermore, a transfer port 68 which is opened and closed by a gate valve G is formed on a sidewall of the large-diameter cylindrical portion 60a of the processing chamber 60.

A gas shower head 69 is provided at a central ceiling portion of the processing chamber 60 opposite to the stage 61. A plurality of gas supply opening 69a for injecting a gas passing through the gas shower head 69 toward the wafer W opens at the bottom of the gas shower head 69. Further, a top surface of the gas shower head 69 is connected to the aforementioned processing gas supply line 43. In addition, a pressure gauge 70 having a pressure measurement range shifted to a higher pressure side as in the aforementioned pressure gauge 47 is provided at a side surface of the processing chamber 60. The pressure gauge 70 is configured to measure a pressure in the processing chamber 60 with high accuracy. Here, it is also possible to use a conventional pressure gauge (e.g., 200 mTorr gauge).

Besides, in the semiconductor manufacturing apparatus 10 of the present embodiment, there is provided a controller 2A includes, e.g., a computer, as illustrated in FIG. 1. The controller 2A includes a CPU 3, a program 4, a memory 5, and a table 6 which stores therein reference data.

The program 4 includes a reference data acquisition program 4a for acquiring reference data D_{A}, a flow rate calculation program 4b for calculating a flow rate of a source gas, a temperature control program 4c for controlling a temperature of the solid source material 20 and the like.

The reference data acquisition program 4a operates to supply the carrier gas to the processing chamber 60, that is, only the carrier gas flows from the carrier gas supply source 45 to the processing chamber 60 via bypass line 46 by opening the valve V2 and closing the valves V1 and V3. Further, the reference data acquisition program 4a controls the pressure gauge 47 to measure, as a pressure measurement value, a pressure reference value P_{A} in the processing gas supply line 43 when flowing the carrier gas having a flow rate reference value Q_{A} through the processing gas supply line 43, and store reference data D_{A} composed of the pressure reference value P_{A} and the flow rate reference value Q_{A} of the carrier gas.

The flow rate calculation program 4b operates to supply the carrier gas to the source container 40 at the same flow rate when acquiring the reference data D_{A}, and measure, as a pressure measurement value, a pressure P_{B} of the processing gas containing the source gas and the carrier gas flowing from the source container 40 to the processing gas supply line 43 by the pressure gauge 47, the pressure P_{B} being measured as comparative data when closing the valve V2 and opening the valves V1 and V3, and calculate the flow rate of the source gas flowing in the processing gas supply line 43 based on the reference data D_{A} obtained by the reference data acquisition program 4a and comparative data P_{B} stored in the memory 5. This calculation is specifically represented by the following equation.

First, a gas flow rate, a gas pressure and a gas exhaust rate in the processing gas supply line 43 are expressed as Q (Pa·m³/sec), P (Pa) and S (m³/sec), respectively. Further, volume of a gas line provided at the upstream side than the pressure gauge 47 is expressed as V (m³), and pressure variation in the gas line per unit time is expressed as dP/dt (Pa/sec). They satisfy the following correlation Eq. (1):

V·dP/dt=−P·S+Q Eq. (1).

A gas flow rate, a gas pressure and a gas exhaust rate when acquiring the reference data D_{A} are expressed as Q_{A}, P_{A} and S_{A}, respectively. The pressure does not change in a steady state, so that dP/dt becomes zero. Therefore, Eq. (2) is obtained from Eq. (1):

Q_{A}=S_{A}·P_{A} Eq. (2).

A gas flow rate, a gas pressure and a gas exhaust rate when acquiring the comparative data P_{B} are expressed as Q_{B}, P_{B} and S_{B}, respectively. The pressure does not change in a steady state, so that dP/dt becomes zero. Therefore, Eq. (3) is obtained from Eq. (1):

Q_{B}=S_{B}·P_{B} Eq. (3).

Here, the flow rate of the carrier gas in the case of acquiring the reference data D_{A} is the same as that in the case of acquiring the comparative data P_{B}. Thus, if the flow rate of the source gas in the case of acquiring the comparative data P_{B} is expressed as Q_{C}, Eq. (4) is obtained from Eq. (3):

Q_{B}=S_{B}·P_{B}=Q_{A}+Q_{C} Eq. (4).

At this time, if the flow rate Q_{C} of the source gas is considerably smaller (by 1/100 or less) than the flow rate reference value Q_{A} of the carrier gas, S_{A} is supposed to be approximately the same as S_{B}. Accordingly, Eq. (5) is obtained by combining Eq. (2) with Eq. (4):

Q_{C}=Q_{A}·(P_{B}−P_{A})/P_{A} (5).

If ΔP is equal to P_{B}−P_{A}, Eq. (6) is obtained from Eq. (5):

Q_{C}=Q_{A}·ΔP/P_{A} Eq. (6).

Therefore, the flow rate Q_{C} of the source gas can be obtained based on the reference data D_{A} (P_{A} and Q_{A}) and the comparative data P_{B}. Here, if the unit of the flow rates Q_{A} and Q_{C} (Pa·m³/sec) is converted into the unit of the flow rates A and C (sccm), which is actually employed, Eq. (6) can be written as Eq. (7):

C=A·ΔP/P_{A} Eq. (7).

Moreover, the temperature of the source material container 40 and the pressure in the processing chamber 60 in the case of acquiring the reference data D_{A} are the same as those in the case of acquiring the comparative data P_{B}. Further, as described above, the flow rate Q_{C} (C) of the source gas is calculated whenever a recipe is changed, especially whenever a pressure in the processing chamber 60 or a flow rate of the carrier gas is changed. Therefore, the reference data D_{A} may be stored in the table 6. That is, the table 6 can store therein the measured reference data (D_{A1}, D_{A2}, . . . , D_{An} (n being a natural number)) for respective recipes of a plurality of film forming conditions (a temperature of the wafer W, a pressure in the processing chamber 60, a flow rate of a carrier gas and the like) in the processing module 50. Therefore, when the flow rate of the source gas is calculated by the flow rate calculation program 4b, the appropriate reference data D_{An} for the recipe used at that time may be read from the memory 5.

The temperature control program 4c operates to control the flow rate of the source gas flowing in the processing gas supply line 43, i.e., the flow rate Q_{C} of the source gas, which is calculated by the flow rate calculation program 4b. To be specific, the output of the power supply 41a to the heating unit 41 that is heating the source material container 40 is controlled by the temperature control program 4c. The flow rate of the source gas supplied to the processing chamber 60 is accurately controlled to a preset flow rate by the temperature control program 4c. As a result, the film forming amount on the wafer W in the processing chamber 60 can be controlled so that a predetermined film thickness is obtained.

In general, these programs 4 (including programs for inputting or displaying processing parameters) are stored in a storage unit 2B such as a computer storage medium, e.g., a flexible disk, a compact disk, an MO (magneto-optical disk), a hard disk or the like, and are installed in the controller 2A.

Hereinafter, a semiconductor manufacturing method using the semiconductor manufacturing apparatus 10 will be described.

(Reference Data D_{A} Acquisition)

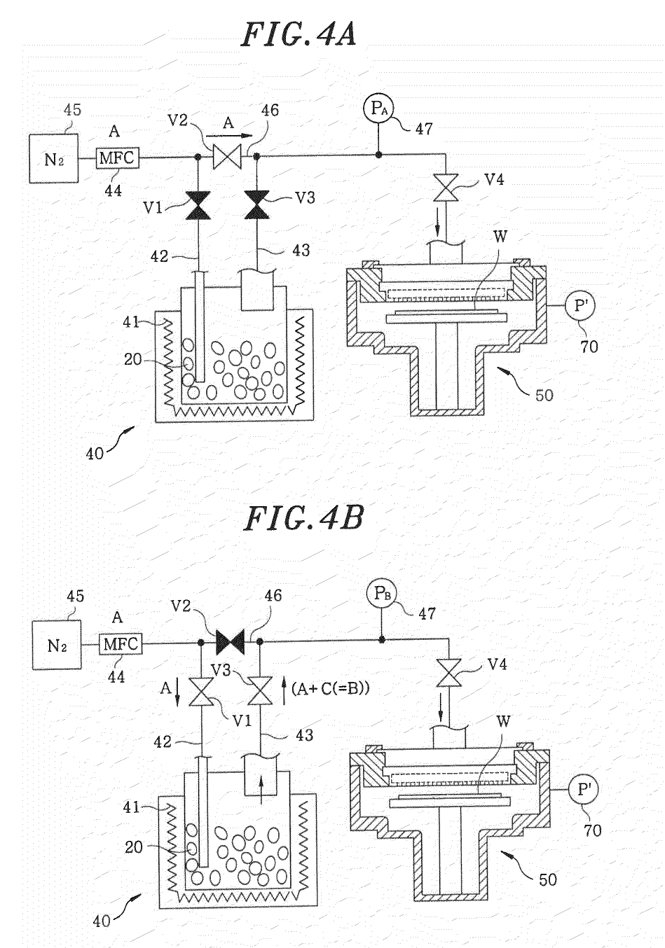

As shown in FIG. 4A, a flow rate A of the carrier gas is set to, e.g., 300 sccm, by the MFC 44. Next, the valve V2 opens, and an opening degree of the butterfly valve 80 (see FIG. 3) is controlled so that the pressure in the processing chamber 60 becomes a predetermined pressure P′, e.g., 17.3 Pa (130 mTorr). Then, the pressure reference value P_{A} of the carrier gas flowing in the processing gas supply line 43 is measured by the pressure gauge 47. Thereafter, the pressure reference value P_{A} and the flow rate A (Q_{A}) of the carrier gas are acquired and stored as the reference data D_{A}. Here, the stored flow rate of the carrier gas may be the set value or a value measured by the MFC 44.

Basically, the reference data D_{A} is acquired when a new recipe is implemented. As set forth above, it is preferable to acquire and store, as a table, the reference data D_{A} corresponding to each of the recipes.

(Comparative Data P_{B} Acquisition)

As illustrated in FIG. 4B, a flow rate of the carrier gas is set to the flow rate A same as that in the case of acquiring the reference data D_{A} by the MFC 44. Next, by closing the valve V2 and opening the valves V1 and V3, the carrier gas flows in the source material container 40, and then, the carrier gas and the source gas flows as the processing gas from the source material container 40 heated in advance to a predetermined temperature, e.g., 80° C., to the processing gas supply line 43. Thereafter, the pressure of the processing gas flowing in the processing gas supply line 43 is measured by the pressure gauge 47. This measured pressure is acquired as the comparative data P_{B}.

Thereafter, as described above, the flow rate of the source gas flowing in the processing gas supply line 43 is calculated by the flow rate calculation program 4b.

(Source Gas Flow Rate Control)

When the calculated flow rate C of the source gas is different from a flow rate of the source gas set in accordance with the recipe, the output value of the power supply 41a to the heating unit 41 is changed by the temperature control program 4c. By controlling the temperature in the source material container 40, the flow rate of the source gas is controlled.

When the preset flow rate of the source gas cannot be obtained, the cycle of acquiring reference data D_{A}, and the comparative data P_{B}, and controlling the flow rate of the source gas is repeatedly carried out while changing the flow rate of the carrier gas and the like.

When the desired flow rate of the source gas is obtained, the wafer W is mounted on the stage 61, and a process for forming, e.g., a ruthenium film, is carried out. The film forming process is performed for a predetermined period of time while controlling the flow rate C of the source gas to a constant level so that a desired film thickness can be obtained.

In accordance with the above embodiment, in order to supply the source gas produced by sublimating the solid source material 20 into the processing chamber 60, first, only the carrier gas is supplied into the processing chamber from the processing gas supply line 43 via the bypass line 46. The pressure reference value P_{A} and the flow rate reference value Q_{A} obtained at that time is acquired as the reference data D_{A}. Next, the carrier gas having the unaltered flow rate is supplied into the processing chamber 60 via the source material container 40 together with the source gas. The pressure measured at that time is acquired as the comparative data P_{B}. The flow rate C of the source gas is calculated based on the comparative data P_{B} and the reference data D_{A}.

Accordingly, the flow rate of the source gas can be simply calculated without using a flow meter such as a mass flow controller or a mass flow meter. For that reason, small-diameter line does not need to be used due to the elimination of the aforementioned flow meter and, hence, a large-diameter line can be used for the processing gas supply line 43.

Accordingly, the conductance of the processing gas supply line 43 can be increased, and the pressure in the source material container 40 can be maintained at a low level, thus facilitating the sublimation of the source gas. Further, the synergy effect of the facilitated sublimation of the source gas and the increased conductance of the processing gas supply line 43 makes it possible to increase the supply amount of the source gas and ensure a high film forming rate.

Moreover, the flow rate of the source gas can be rapidly controlled to a desired level by controlling the temperature of the solid source material 20 even when, e.g., the sublimation amount of the solid source material 20 decreases due to the decreased amount of the solid source material 20 during the film formation, or even when, e.g., the sublimation amount of the solid source material 20 increases due to the increased surface area of the solid source material 20 by the sublimation of the solid source material 20. Accordingly, the fine flow rate control can be carried out. As a result, a uniform film thickness can be ensured between the wafers W, which suppresses reduction of a production yield.

In the present embodiment, the flow rate A of the carrier gas is considerably larger than the flow rate C of the source gas produced by sublimating the solid source material 20 having a very low vapor pressure. Based on this, it is considered that a gas exhaust flow rate S_{A} measured in the case of acquiring the reference data D_{A} is approximately the same as a gas exhaust flow rate S_{B} measured in the case of acquiring the comparative data P_{B}. As a result, the flow rate C of the source gas can be simply calculated. Further, the flow rate C of the source gas is directly calculated (not being calculated from the temperature of the gas as in the MFC), so that it is unnecessary to execute conversion for correcting effects of specific heat, density and thermal conductivity of the gas. Subsequently, the calculation process can be simplified, and any type of gas can be used.

In a conventional pressure gauge used for a low vacuum range, it is difficult to measure a small amount of change in a gas pressure in the low vacuum range. However, the pressure gauge 47 in which a pressure measurement range of a high-resolution pressure gauge used in a high vacuum range is shifted to a higher pressure side is used so that the accuracy of the pressure measurement value in a low vacuum range can be increased. Therefore, the flow rate C of the source gas can be obtained with high accuracy without using a flow rate measuring device.

Since the flow rate C of the source gas can be calculated accurately, the consumption amount (remaining amount) of the solid source material 20 can be obtained. Accordingly, it is possible to accurately know the timing of replenishing the solid source material 20, the timing of replacing the source material container 40 and the like.

Although the gas supply unit 11 of the present embodiment employs a large-diameter line as the processing gas supply line 43, the present invention is not limited thereto. Even in the case of employing a line that is small enough for a device such as a flow meter (MFC) or the like to be installed thereon, a drawback that a pressure at the upstream side of the line increases can be suppressed not by installing the flow meter or the like.

In addition, although the film formation is performed by heating the wafer W by the heater 61a of the stage 61, the film formation may be performed by using a plasma of a source gas in a state where a high frequency power or the like is connected with a gas shower head 69. In that case, the high frequency power serves as the aforementioned gas decomposition device.

In the above-described example, ruthenium carbonyl is used as the solid source material 20. However, it is not limited thereto, and any compound, e.g. tungsten carbonyl or the like, can be used as long as it can be sublimated to a source gas.

What is claimed is:

1. A gas supply method for supplying a source gas produced by heating and sublimating a solid source material in a source material container to a consuming area, the gas supply method comprising the steps of:
(a) flowing a carrier gas through a processing gas supply line that communicates with the consuming area and measuring a gas pressure in the processing gas supply line;
(b) heating the solid source material contained in the source material container to produce the source gas;
(c) supplying a carrier gas which has the same flow rate as the carrier gas in the step (a) to the source material container and measuring a gas pressure in the processing gas supply line while flowing the source gas together with the carrier gas through the processing gas supply line; and
(d) calculating the flow rate of the source gas based on the pressure measurement value obtained in the step (a), the pressure measurement value obtained in the step (c), and the flow rate of the carrier gas.

2. The gas supply method of claim 1, further comprising, after the step (d), a step of adjusting a flow rate of the source gas and controlling a heating temperature of the solid source material based on a preset flow rate of the source gas and the calculated flow rate of the source gas obtained in the step (d).

3. The gas supply method of claim 1, wherein an inner diameter of the processing gas supply line extended from the source material container to the consuming area is greater than or equal to about 1.9 cm (0.75 inch).

4. The gas supply method of claim 1, wherein the consuming area is a processing module for performing a film forming process on a substrate in a processing chamber by decomposing the source gas under the vacuum atmosphere.

5. A gas supply device for supplying a source gas produced by heating and sublimating a solid source material in a source material container to a consuming area, the gas supply device comprising:
a source material container for storing therein a solid source material;
a heating unit for heating the solid source material in the source material container;
a carrier gas inlet line provided between a carrier gas supply source and the source material container;
a processing gas supply line provided between the source material container and the consuming area;
a bypass line installed between the carrier gas inlet line and the processing gas supply line;
a pressure measuring unit provided at a downstream side of a connecting position of the bypass line on the processing gas supply line;
a flow path switching unit for switching a flow path of the carrier gas between a flow path for causing the carrier gas to flow from the carrier gas inlet line to the processing gas supply line via the bypass line and a flow path for causing the carrier gas to flow from the carrier gas inlet line to the processing gas supply line via the source material container; and
a controller for controlling a flow rate of the source gas flowing in the processing gas supply line,
wherein the controller performs:
storing a reference data including a measured flow rate of the carrier gas and a pressure measurement value obtained by the pressure measuring unit while the carrier gas is flowing in the processing gas supply line via the bypass line;
obtaining a pressure measurement value by the pressure measuring unit while the carrier gas having the unaltered flow rate and the source gas are flowing together in the processing gas supply line via the source material container; and
calculating a flow rate of the source gas based on the measured pressure measurement values and the reference data.

6. The gas supply device of claim 5, wherein the controller adjusts a flow rate of the source gas and controls a power supplied to the heating unit based on a preset flow rate of the source gas and a calculated flow rate of the source gas.

7. The gas supply device of claim 5, wherein an inner diameter of the processing gas supply line is greater than or equal to about 1.9 cm (0.75 inch).

8. A semiconductor manufacturing apparatus comprising:
the gas supply device described in any one of claims 5 to 7;
a processing module including a processing chamber as a consuming area, for performing film formation on a substrate by decomposing a source gas under the vacuum atmosphere,
wherein the controller has the reference data for film forming recipes executed in the processing module.

9. A storage medium which stores therein a program used in a gas supply device for supplying a source gas produced by heating and sublimating a solid source material in a source material container to a consuming area, wherein the program includes steps of executing the gas supply method described in any one of claims 1 to 4.
